(19) United States
(12) Patent Application Publication
(10) Pub. No.: US 2020/0209746 A1
(43) Pub. Date: Jul. 2, 2020

(54) POSITIVE-TYPE PHOTOSENSITIVE COMPOSITION AND CURED FILM USING THE SAME

(71) Applicant: ROHM AND HAAS ELECTRONIC MATERIALS KOREA LTD., Chungcheongnam-do (KR)

(72) Inventors: Jong-Ho NA, Gyeonggi-do (KR); Geun HUH, Gyeonggi-do (KR); Kahee SHIN, Gyeonggi-do (KR); Eun-Young LEE, Gyeonggi-do (KR); Jong Han YANG, Gyeonggi-do (KR)

(21) Appl. No.: 16/710,564

(22) Filed: Dec. 11, 2019

(30) Foreign Application Priority Data
Dec. 28, 2018 (KR) 10-2018-0171864

(51) Int. Cl. G03F 7/039; C08L 83/04; C08L 33/10; C08L 33/06; G03F 7/022; G03F 7/075

(52) U.S. Cl. CPC G03F 7/0392; C08L 83/04; C08L 33/10; G03F 7/0757; C08L 33/064; G03F 7/022; C08L 33/068

(57) ABSTRACT

The present invention relates to a positive-type photosensitive resin composition and a cured film prepared therefrom. In the composition, the developability (i.e., development rate) is appropriately adjusted by the interaction between the photoactive compound of a polymer, and/or the photoactive compound of a monomer, containing a repeat unit having a specific structure and the two kinds of a binder resin (i.e., a siloxane copolymer and an acrylic copolymer). Thus, it is possible to reduce the rate of loss in the thickness of a cured film during the development step. In addition, the use of the composition allows an increase in the exposed portion (i.e., the portion exposed to light) by the interaction between the two kinds of a binder resin and the photoactive compound, which increases the solubility in a developer, whereby the sensitivity can be enhanced. Further, the composition is capable of forming a cured film that is excellent in film retention rate and has a smooth surface even upon the post-bake.

### TECHNICAL FIELD

The present invention relates to a positive-type photosensitive resin composition capable of forming a cured film that is excellent in sensitivity, resolution, and film retention rate, and a cured film prepared therefrom to be used in a liquid crystal display, an organic EL display, and the like.

### BACKGROUND ART

In general, a positive-type photosensitive resin composition that requires fewer processing steps is widely employed in liquid crystal display devices, organic EL display devices, and the like.

However, a planarization film or a display element using a conventional positive-type photosensitive resin composition has lower sensitivity than a planarization film and a display element using a negative-type photosensitive resin composition. Therefore, the sensitivity of the former needs to be improved.

Meanwhile, conventional positive photosensitive resin compositions generally comprise an alkali-soluble resin such as a siloxane polymer and an acrylic polymer as a binder resin, along with a photosensitive agent such as a quinonediazide-based compound, an aromatic aldehyde, or the like (see Japanese Laid-open Patent Publication No. 1996-234421).

However, when a cured film is formed using such a positive-type photosensitive resin composition, the rate of loss in the thickness of the cured film by a developer during the developing step is large, and there is a limit to achieving sufficiently satisfying film retention rate, sensitivity, resolution, and the like.

### DISCLOSURE OF INVENTION

### Technical Problem

Accordingly, the present invention aims to provide a positive-type photosensitive resin composition, which comprises two kinds of a binder resin and is capable of forming a cured film that is excellent in sensitivity and resolution with a smooth surface as the development rate is properly controlled during the development, and a cured film prepared therefrom to be used in a liquid crystal display, an organic EL display, and the like.

### Solution to Problem

In order to accomplish the above object, the present invention provides a positive-type photosensitive resin composition, which comprises (A) a siloxane copolymer; (B) an acrylic copolymer; and (C) a photoactive compound comprising a compound containing a repeat unit represented by the following Formula 1:

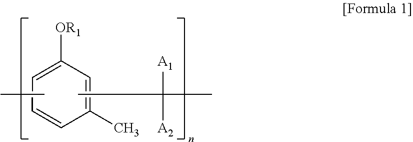

In the above Formula 1, A₁ and A₂ are each independently hydrogen, a hydroxyl group, a phenol group, a C₁₋₄ alkyl group, a C₆₋₁₅ aryl group, or a C₁₋₄ alkoxy group, R₁ is hydrogen or,

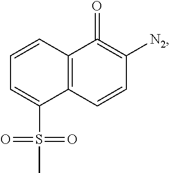

and n is an integer of 3 to 15.

In order to accomplish another object, the present invention provides a cured film prepared using the positive-type photosensitive resin composition.

### Advantageous Effects of Invention

In the positive-type photosensitive resin composition according to the present invention, the developability (i.e., development rate) is appropriately adjusted by the interaction between the photoactive compound of a polymer, and/or the photoactive compound of a monomer, containing a repeat unit having a specific structure and the two kinds of a binder resin (i.e., a siloxane copolymer and an acrylic copolymer). Thus, it is possible to reduce the rate of loss in the thickness of a cured film during the development step. In addition, the use of the composition allows an increase in the exposed portion (i.e., the portion exposed to light) by the interaction between the two kinds of a binder resin and the photoactive compound, which increases the solubility in a developer, whereby the sensitivity can be enhanced. Further, the composition is capable of forming a cured film that is excellent in film retention rate and has a smooth surface even upon the post-bake.

### BRIEF DESCRIPTION OF DRAWINGS

FIG. 1 shows each photograph of a pattern formed on the surface of a cured film obtained from the compositions of the Examples and the Comparative Examples by an optical microscope.

FIG. 2 shows each photograph of the surface of a cured film obtained from the compositions of the Examples and the Comparative Examples by a scanning electron microscope.

### BEST MODE FOR CARRYING OUT THE INVENTION

The present invention provides a positive-type photosensitive resin composition, which comprises (A) a siloxane copolymer; (B) an acrylic copolymer; and (c) a photoactive compound.

It may optionally further comprise (D) an epoxy compound; (E) a surfactant; (F) an adhesion supplement; and/or (G) a solvent.

Hereinafter, each component of the positive-type photosensitive resin composition will be explained in detail.

As used herein, the term “(meth)acryl” refers to “acryl” and/or “methacryl,” and the term “(meth)acrylate” refers to “acrylate” and/or “methacrylate.”

The weight average molecular weight (g/mole, Da) of each component as described below is measured by gel permeation chromatography (GPC, eluent: tetrahydrofuran) referenced to a polystyrene standard.

(A) Siloxane Copolymer

The photosensitive resin composition comprising the siloxane copolymer (siloxane polymer; A) can be formed into a positive-type pattern by a process proceeding from exposure to light to development.

The siloxane polymer (A) is an alkali-soluble resin for materializing developability in the development step and also plays the role of a base for forming a film upon coating and a structure and a binder for forming a final pattern.

The siloxane polymer (A) includes a condensate of a silane compound and/or a hydrolysate thereof. In such event, the silane compound or the hydrolysate thereof may be a monofunctional to tetrafunctional silane compound. As a result, the siloxane polymer may comprise a siloxane structural unit selected from the following Q, T, D, and M types:
Q type siloxane structural unit: a siloxane structural unit comprising a silicon atom and adjacent four oxygen atoms, which may be derived from, e.g., a tetrafunctional silane compound or a hydrolysate of a silane compound that has four hydrolyzable groups.
T type siloxane structural unit: a siloxane structural unit comprising a silicon atom and adjacent three oxygen atoms, which may be derived from, e.g., a trifunctional silane compound or a hydrolysate of a silane compound that has three hydrolyzable groups.
D type siloxane structural unit: a siloxane structural unit comprising a silicon atom and adjacent two oxygen atoms (i.e., a linear siloxane structural unit), which may be derived from, e.g., a difunctional silane compound or a hydrolysate of a silane compound that has two hydrolyzable groups.
M type siloxane structural unit: a siloxane structural unit comprising a silicon atom and one adjacent oxygen atom, which may be derived from, e.g., a monofunctional silane compound or a hydrolysate of a silane compound that has one hydrolyzable group.

Specifically, the siloxane polymer (A) may comprise a structural unit derived from a silane compound represented by the following Formula 2:

(R₂)ₘSi(OR₃)₄₋ₘ [Formula 2]

In the above Formula 2, m is an integer of 0 to 3, R₂ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and R₃ is each independently hydrogen, C₁₋₆ alkyl, C₂₋₆ acyl, or C₆₋₁₅ aryl, wherein the heteroalkyl, the heteroalkenyl, and the heteroaryl groups each independently have at least one heteroatom selected from the group consisting of O, N, and S.

The compound may be a tetrafunctional silane compound where m is 0, a trifunctional silane compound where m is 1, a difunctional silane compound where m is 2, or a monofunctional silane compound where m is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, butyltrimethoxysilane, 3-glycidoxypropyltrimethoxysilane, 3-glycidoxypropyltriethoxysilane, 2-(3,4-epoxycyclohexyl)ethyltrimethoxysilane, and 2-(3,4-epoxycyclohexyl)ethyltriethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

The conditions for obtaining a hydrolysate or a condensate of the silane compound of the above Formula 2 are not particularly limited.

The weight average molecular weight of the condensate (i.e., siloxane polymer) obtained by the hydrolytic polymerization of the silane compound of the above Formula 2 may be 500 to 50,000 Da, 1,000 to 50,000 Da, 3,000 to 30,000 Da, or 5,000 to 20,000 Da. If the weight average molecular weight of the siloxane polymer is within the above range, it is more preferable in terms of the film formation properties, solubility, dissolution rates in a developer, and the like.

The siloxane polymer (A) may comprise a structural unit derived from a silane compound represented by the above Formula 2 where m is 0 (i.e., Q-type structural unit). Specifically, the siloxane polymer may comprise the structural unit derived from the silane compound represented by the above Formula 2 where m is 0 in an amount of 10 to 50% by mole or 15 to 40% by mole based on an Si atomic mole number. If the amount of the Q-type structural unit is within the above range, the photosensitive resin composition may maintain its solubility to an aqueous alkaline solution at a proper level during the formation of a pattern, thereby preventing any defects caused by a reduction in the solubility or a drastic increase in the solubility of the composition.

The siloxane polymer (A) may comprise a structural unit derived from a silane compound represented by the above Formula 2 where m is 1 (i.e., T-type structural unit). For example, the siloxane polymer may comprise the structural unit derived from the silane compound of the above Formula 2 where m is 1 in an amount ratio of 40 to 99% by mole or 50 to 95% by mole based on an Si atomic mole number. If the amount of the T-type structural unit is within the above range, it is more preferable to form a more precise pattern profile.

In addition, it is more preferable that the siloxane polymer comprises a structural unit derived from a silane compound having an aryl group in terms of the hardness, sensitivity, and retention rate of a cured film. For example, the siloxane polymer may comprise a structural unit derived from a silane compound having an aryl group in an amount of 20 to 80% by mole, 30 to 70% by mole, or 30 to 50% by mole, based on an Si atomic mole number. If the amount of the structural unit derived from a silane compound having an aryl group is within the above range, the compatibility of the siloxane polymer (A) with the photoactive compound (C) is excellent, which may prevent an excessive decrease in sensitivity while attaining more favorable transparency of a cured film.

The structural unit derived from the silane compound having an aryl group may be, for example, a structural unit derived from a silane compound of the above Formula 2 where R₂ is an aryl group, specifically a silane compound of the above Formula 2 where m is 1 and R₂ is an aryl group, more specifically a silane compound of the above Formula 2 where m is 1 and R₂ is a phenyl group (i.e., siloxane structural unit of T-phenyl type).

The term “% by mole based on an Si atomic molar number” as used herein refers to a percentage of the number of moles of Si atoms contained in a specific structural unit with respect to the total number of moles of Si atoms contained in all of the structural units constituting the siloxane polymer.

The molar amount of a siloxane unit in the siloxane polymer may be measured by the combination of Si-NMR, ¹H-NMR, ¹³C-NMR, IR, TOF-MS, elementary analysis, measurement of ash, and the like. For example, in order to measure the molar amount of a siloxane unit having a phenyl group, an Si-NMR analysis is performed on the entire siloxane polymer, followed by an analysis of the phenyl-bound Si peak area and the phenyl-unbound Si peak area. The molar amount can then be computed from the peak area ratio between them.

Meanwhile, the siloxane polymer of the present invention may be a mixture of two or more siloxane polymers having dissolution rates different from each other to an aqueous solution of tetramethylammonium hydroxide (TMAH). If a mixture of two or more siloxane polymers as described above is used as the siloxane polymer, it is possible to improve both of the sensitivity and the chemical resistance of the resin composition.

The photosensitive resin composition of the present invention may comprise the siloxane polymer in an amount of 10 to 90% by weight, 20 to 80% by weight, or 25 to 60% by weight, based on the total weight of the composition on the basis of the solids content excluding solvents. If the content of the siloxane polymer is within the above range, it is possible to maintain the developability of the composition at a suitable level, thereby producing a cured film that is excellent in the film retention and the pattern resolution.
(B) Acrylic copolymer

The positive-type photosensitive resin composition according to the present invention may comprise an acrylic copolymer (B).

The acrylic copolymer (B) may comprise (b-1) a structural unit derived from an ethylenically unsaturated carboxylic acid, an ethylenically unsaturated carboxylic anhydride, or a combination thereof; (b-2) a structural unit derived from an unsaturated compound containing an epoxy group; and (b-3) a structural unit derived from an ethylenically unsaturated compound different from the structural units (b-1) and (b-2).

The acrylic copolymer (B) is an alkali-soluble resin for materializing developability in the development step and also plays the role of a base for forming a film upon coating and a structure for forming a final pattern.

(b-1) Structural Unit Derived from an Ethylenically Unsaturated Carboxylic Acid, an Ethylenically Unsaturated Carboxylic Anhydride, or a Combination Thereof

The structural unit (b-1) is derived from an ethylenically unsaturated carboxylic acid, an ethylenically unsaturated carboxylic anhydride, or a combination thereof. The ethylenically unsaturated carboxylic acid, the ethylenically unsaturated carboxylic anhydride, or a combination thereof is a polymerizable unsaturated compound containing at least one carboxyl group in the molecule. It may be at least one selected from an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl]phthalate, and the like. But it is not limited thereto. (Meth)acrylic acid among the above is preferable from the viewpoint of developability.

The amount of the structural unit (b-1) may be 5 to 50% by mole, preferably 10 to 40% by mole, based on the total moles of the structural units constituting the acrylic copolymer (B). Within the above range, it is possible to attain a pattern formation of a film while maintaining favorable developability.

(b-2) Structural Unit Derived from an Unsaturated Compound Containing an Epoxy Group

The structural unit (b-2) is derived from an unsaturated monomer containing at least one epoxy group. Particular examples of the unsaturated monomer containing at least one epoxy group may include glycidyl (meth)acrylate, 4-hydroxybutyl acrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, and a combination thereof. Glycidyl (meth)acrylate, 3,4-epoxycyclohexyl (meth)acrylate, 4-hydroxybutyl acrylate glycidyl ether, or a combination thereof is preferable from the viewpoint of storage stability at room temperature and solubility.

The amount of the structural unit derived from an unsaturated compound containing at least one epoxy group (b-2) may be 1 to 45% by mole, preferably 3 to 30% by mole, based on the total moles of the structural units constituting the acrylic copolymer (B). Within the above range, the storage stability of the composition may be maintained, and the film retention rate upon post-bake may be advantageously enhanced.

(b-3) Structural Unit Derived from an Ethylenically Unsaturated Compound Different from the Structural Units (b-1) and (b-2)

The structural unit (b-3) is derived from an ethylenically unsaturated compound different from the structural units (b-1) and (b-2). The ethylenically unsaturated compound different from the structural units (b-1) and (b-2) may be at least one selected from the group consisting of an ethylenically unsaturated compound having an aromatic ring such as phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyl toluene, divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, dicyclopentenyloxyethyl (meth)acrylate, glycidyl (meth)acrylate, 3,4-epoxybutyl (meth)acrylate, 4,5-epoxypentyl (meth)acrylate, 3,4-epoxyhexyl (meth)acrylate, 5,6-epoxyhexyl (meth)acrylate, and 6,7-epoxyheptyl (meth)acrylate; an N-vinyl tertiary amine containing an N-vinyl group such as N-vinyl pyrrolidone, N-vinyl carbazole, and N-vinyl morpholine; an unsaturated ether such as vinyl methyl ether and vinyl ethyl ether; and an unsaturated imide such as N-phenylmaleimide, N-(4-chlorophenyl)maleimide, N-(4-hydroxyphenyl)maleimide, and N-cyclohexylmaleimide.

The amount of the structural unit (b-3) may be 5 to 70% by mole, preferably 15 to 65% by mole, based on the total moles of the structural units constituting the acrylic copolymer (B). Within the above range, it is possible to control the reactivity of the acrylic copolymer (i.e., an alkali-soluble resin) and to increase the solubility thereof in an aqueous alkaline solution, so that the applicability of the photosensitive resin composition can be remarkably enhanced.

The acrylic copolymer (B) may be prepared by compounding each of the compounds that provide the structural units (b-1), (b-2), and (b-3), adding a molecular weight controlling agent, a polymerization initiator, a solvent, and the like thereto, followed by charging nitrogen thereto and slowly stirring the mixture for polymerization. The molecular weight controlling agent may be a mercaptan compound such as butyl mercaptan, octyl mercaptan, lauryl mercaptan, or the like, or an α-methylstyrene dimer, but it is not particularly limited thereto.

The polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide; lauryl peroxide; t-butyl peroxypivalate; 1,1-bis(t-butylperoxy)cyclohexane, or the like, but it is not limited thereto. The polymerization initiator may be used alone or in combination of two or more thereof.

In addition, the solvent may be any solvent commonly used in the preparation of an acrylic copolymer (B). It may preferably be methyl 3-methoxypropionate or propylene glycol monomethyl ether acetate (PGMEA).

The weight average molecular weight (Mw) of the copolymer thus prepared may be in the range of 500 to 50,000 Da, preferably 3,000 to 30,000 Da. Within the above range, the adhesiveness to a substrate is excellent, the physical and chemical properties are good, and the viscosity is proper.

The acrylic copolymer (B) may be employed in an amount of 10 to 90% by weight, 20 to 80% by weight, or 25 to 60% by weight, based on the total weight of the photosensitive resin composition on the basis of the solids content.

The siloxane copolymer (A) may be employed in an amount of 10 to 90 parts by weight, 20 to 80 parts by weight, or 25 to 60 parts by weight, based on 100 parts by weight of the acrylic copolymer.

Within the above range, the developability is appropriately controlled, which is advantageous in terms of the film retention and the resolution of a pattern.

(C) Photoactive Compound

The positive-type photosensitive resin composition according to the present invention may comprise (c-1) a compound containing a repeat unit represented by the following Formula 1 as the photoactive compound (C). It may optionally further comprise (c-2) a quinonediazide-based monomer.

(c-1) Compound Containing a Repeat Unit Represented by the Following Formula 1

The positive-type photosensitive resin composition according to the present invention may comprise a polymer compound containing an ortho-quinonediazide group as shown below as the photoactive compound (C).

Specifically, the photoactive compound (C) may comprise a compound (c-1) containing a repeat unit represented by the following Formula 1.

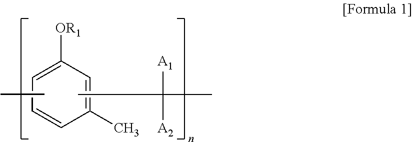

In the above Formula 1, A₁ and A₂ are each independently hydrogen, a hydroxyl group, a phenol group, a C₁₋₄ alkyl group, a C₆₋₁₅ aryl group, or a C₁₋₄ alkoxy group, R₁ is hydrogen or

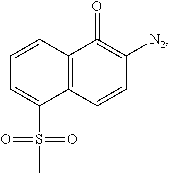

and n is an integer of 3 to 15.

More specifically, the compound (c-1) containing the repeat unit represented by the above Formula 1 may be an ester of 1,2-benzoquinonediazide-4-sulfonic acid, 1,2-naphthoquinonediazide-4-sulfonic acid, 1,2-naphthoquinonediazide-5-4-sulfonic acid, or the like, and/or a compound in which the hydroxyl group thereof is substituted with an amino group.

The compound (c-1) containing the repeat unit represented by the above Formula 1 may be used alone or in combination with an aromatic aldehyde-based alkali-soluble resin (e.g., a polyhydroxy aromatic compound).

For examples, a polyhydroxyalkyl compound such as glycerin, pentaerythritol, and the like, or a polyhydroxy aromatic compound such as a novolac resin, bisphenol A, a gallic acid ester, quercetin, morin, polyhydroxy benzophenone, or the like may be used in combination with an ester of 1,2-benzoquinonediazide-4-sulfonic acid, 1,2-naphthoquinonediazide-4-sulfonic acid, 1,2-naphthoquinonediazide-5-4-sulfonic acid, or the like. Preferably, a novolac resin and/or polyhydroxy benzophenone may be used in combination with an ester of 1,2-naphthoquinonediazide-5-sulfonic acid.

In such event, the substitution ratio (i.e., esterification ratio) of the novolac resin may be 10 to 70% or 25 to 60% (i.e., an esterified product of novolac resin/total novolac resin×100). The substitution ratio of the polyhydroxy benzophenone may be 50 to 95% (i.e., an esterified product of polyhydroxy benzophenone/total polyhydroxy benzophenone×100). Within the above ranges, the resolution and sensitivity of the composition can be further enhanced. If the substitution ratios are low, the resolution is deteriorated. If the substitution ratios are too high, the sensitivity may be deteriorated.

The compound (c-1) containing the repeat unit represented by the above Formula 1 may be employed in an amount of 5 to 100% by weight, 5 to 80% by weight, 10 to 70% by weight, or 15 to 55% by weight, based on the total weight of the photoactive compound (C) on the basis of solids content. Within the above content range, a pattern is more readily formed, the rate of loss in the thickness of a cured film during the developing step is reduced, and the resolution can be further enhanced. In addition, the surface of a coating film upon the formation thereof is not roughened, whereby the roughness can be improved.

(c-2) Quinonediazide-Based Monomer

The positive-type photosensitive resin composition according to the present invention may further comprise a quinonediazide-based monomer (c-2), specifically, a 1,2-quinonediazide-based compound as the photoactive compound (C).

The 1,2-quinonediazide-based compound is not particularly limited as long as it is used as a photosensitive agent in the photoresist field and has a 1,2-quinonediazide-based structure.

Examples of the 1,2-quinonediazide-based compound include an ester compound of a phenolic compound and 1,2-benzoquinonediazide-4-sulfonic acid or 1,2-benzoquinonediazide-5-sulfonic acid; an ester compound of a phenolic compound and 1,2-naphthoquinonediazide-4-sulfonic acid or 1,2-naphthoquinonediazide-5-sulfonic acid; a sulfonamide compound of a phenolic compound in which the hydroxyl group is substituted with an amino group and 1,2-benzoquinonediazide-4-sulfonic acid or 1,2-benzoquinonediazide-5-sulfonic acid; a sulfonamide compound of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

Examples of the phenolic compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, bis[4-hydroxy-3-(2-hydroxy-5-methylbenzyl)-5-dimethylphenyl]methane, and the like.

More particular examples of the 1,2-quinonediazide-based compound (c-2) include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]-1-methylethyl]phenyl] ethylidene]bisphenol and 1,2-naphthoquinonediazide-4-sulfonic acid, an ester of 4,4′-[1-[4-[1-[4-hydroxyphenyl]-1-methylethyl]phenyl] ethylidene]bisphenol and 1,2-naphthoquinonediazide-5-sulfonic acid, and the like. If the compounds exemplified above are used as the 1,2-quinonediazide-based compound, the transparency of the photosensitive resin composition may be further enhanced.

The photoactive compound (C) may be employed in an amount of 2 to 50 parts by weight, 5 to 35 parts by weight, or 15 to 30 parts by weight, based on 100 parts by weight of the acrylic copolymer (B) on the basis of the solids content.

If the amount of the photoactive compound (C) is within the above range, a pattern is more readily formed from the resin composition, and it is possible to prevent such defects as a rough surface of a coated film upon the formation thereof and such a pattern shape as scum appearing at the bottom portion of the pattern upon development, and to secure excellent transmittance.

(D) Epoxy Compound

The epoxy compound may increase the internal density of the resin composition, to thereby improve the chemical resistance of a cured film formed therefrom.

The epoxy compound (D) may be a homo-oligomer or a hetero-oligomer of an unsaturated monomer containing at least one epoxy group.

Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, and p-vinylbenzyl glycidyl ether. Preferably, glycidyl methacrylate may be used.

The epoxy compound may be synthesized by any conventional methods well known in the art. An example of the commercially available epoxy compound may be GHP03HP (glycidyl methacrylate homopolymer, Miwon Commercial Co., Ltd.).

The epoxy compound (D) may further comprise the following structural unit.

Particular examples thereof may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether, vinyl ethyl ether, allyl glycidyl ether and 2-methylallyl glycidyl ether; an unsaturated imide such as N-phenylmaleimide, N-(4-chlorophenyl)maleimide, N-(4-hydroxyphenyl)maleimide, and N-cyclohexylmaleimide. The structural unit derived from the compounds exemplified above may be contained in the epoxy compound alone or in combination of two or more thereof.

Specifically, the styrene compounds are preferred among these examples from the viewpoint of polymerizability of the composition. In particular, it is more preferable in terms of the chemical resistance that the epoxy compound does not contain a carboxyl group by way of not using a structural unit derived from a monomer containing a carboxyl group among these compounds.

The weight average molecular weight of the epoxy compound (D) may be 100 to 30,000 Da, 1,000 to 20,000, 1,000 to 15,000, or 6,000 to 10,000 Da. If the weight average molecular weight of the epoxy compound is at least 100 Da, the hardness of a cured film may be more favorable. If it is 30,000 Da or less, the cured film may have a uniform thickness, which is suitable for planarizing any steps thereon.

The epoxy compound (D) may be employed in an amount of 0 to 40 parts by weight, 1 to 30 parts by weight, or 2 to 20 parts by weight, based on 100 parts by weight of the acrylic copolymer. Within the above content range, the sensitivity and the chemical resistance of the photosensitive resin composition are more favorable.

(E) Surfactant

The photosensitive resin composition of the present invention may further comprise a surfactant (E) to enhance its coatability, if desired.

The kind of the surfactant (E) is not particularly limited. Examples thereof may include fluorine-based surfactants, silicon-based surfactants, non-ionic surfactants, and the like.

Specific examples of the surfactant (E) may include fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141, S-145, S-382, SC-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; and organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. They may be used alone or in combination of two or more thereof.

The surfactant (E) may be employed in an amount of 0.001 to 5 parts by weight or 0.05 to 1 part by weight based on 100 parts by weight of the acrylic copolymer (B) on the basis of the solids content. Within the above content range, the coatability of the composition is excellent, whereby such defects as surface stains or surface unevenness do not occur.

(F) Adhesion Supplement

The photosensitive resin composition of the present invention may further comprise an adhesion supplement (F) to enhance the adhesiveness to a substrate.

The adhesion supplement (F) may have at least one reactive group selected from the group consisting of a carboxyl group, a (meth)acryloyl group, an isocyanate group, an amino group, a mercapto group, a vinyl group, and an epoxy group.

The kind of the adhesion supplement (F) is not particularly limited. It may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, β-(3,4-epoxycyclohexyl)ethyltrimethoxysilane, 3-isocyanate propyl triethoxysilane, and a mixture thereof.

Preferred is γ-glycidoxypropyltrimethoxysilane, γ-glycidoxypropyltriethoxysilane, 3-isocyanate propyl triethoxysilane, or N-phenylaminopropyltrimethoxysilane, which is capable of enhancing the film retention rate and the adhesiveness to a substrate.

The adhesion supplement (F) may be employed in an amount of 0.001 to 5 parts by weight or 0.01 to 4 parts by weight based on 100 parts by weight of the acrylic copolymer (B) on the basis of the solids content. Within the above content range, the adhesiveness to a substrate may be further enhanced.

(G) Solvent

The photosensitive resin composition of the present invention may be prepared in the form of a liquid composition in which the above components are mixed with a solvent (G). The solvent (G) may be, for example, an organic solvent.

The amount of the solvent (G) in the positive-type photosensitive resin composition according to the present invention is not particularly limited. For example, the solvent may be employed such that the solids content is 10 to 90% by weight or 15 to 85% by weight based on the total weight of the composition. The solid content refers to the components constituting the resin composition of the present invention, excluding solvents. If the amount of the solvent is within the above range, the coating of the composition can be readily carried out, while the flowability thereof can be maintained at a proper level.

The solvent (G) of the present invention is not particularly limited as long as it can dissolve the above-mentioned components and is chemically stable. For example, the solvent may be an alcohol, an ether, a glycol ether, an ethylene glycol alkyl ether acetate, diethylene glycol, a propylene glycol monoalkyl ether, a propylene glycol alkyl ether acetate, a propylene glycol alkyl ether propionate, an aromatic hydrocarbon, a ketone, an ester, and the like.

Particular examples of the solvent (G) include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Preferred among the above are ethylene glycol alkyl ether acetates, diethylene glycols, propylene glycol monoalkyl ethers, propylene glycol alkyl ether acetates, ketones, and the like. In particular, preferred are diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, 4-hydroxy-4-methyl-2-pentanone, and the like. The solvents exemplified above may be used alone or in combination of two or more thereof.

In addition, the photosensitive resin composition of the present invention may further comprise other additives as long as the physical properties of the photosensitive resin composition are not adversely affected.

The photosensitive resin composition according to the present invention may be used as a positive-type photosensitive resin composition.

In particular, in the positive-type photosensitive resin composition according to the present invention, the developability (i.e., development rate) is appropriately adjusted by the interaction between the photoactive compound of a polymer, and/or the photoactive compound of a monomer, containing a repeat unit having a specific structure and the two kinds of a binder resin (i.e., a siloxane copolymer and an acrylic copolymer). Thus, it is possible to reduce the rate of loss in the thickness of a cured film during the development step. In addition, the use of the composition allows an increase in the exposed portion (i.e., the portion exposed to light) by the interaction between the two kinds of a binder resin and the photoactive compound, which increases the solubility in a developer, whereby the sensitivity can be enhanced. Further, the composition is capable of forming a cured film that is excellent in film retention rate and has a smooth surface even upon the post-bake.

The present invention provides a cured film formed from the photosensitive resin composition.

The cured film may be formed by a method known in the art, for example, a method in which the photosensitive resin composition is coated on a substrate and then cured. More specifically, in the curing step, the photosensitive resin composition coated on a substrate may be subjected to pre-bake at a temperature of, for example, 60 to 130° C. to remove solvents; then exposed to light using a photomask having a desired pattern; and subjected to development using a developer, for example, a tetramethylammonium hydroxide (TMAH) solution to form a pattern on the coating layer. Thereafter, the patterned coating layer, if necessary, is subjected to post-bake, for example, at a temperature of 150 to 300° C. for 10 minutes to 5 hours to prepare a desired cured film. The exposure to light may be carried out at an exposure rate of 10 to 200 mJ/cm² based on a wavelength of 365 nm in a wavelength band of 200 to 500 nm. According to the process of the present invention, it is possible to easily form a desired pattern from the viewpoint of the process.

The coating of the photosensitive resin composition onto a substrate may be carried out by a spin coating method, a slit coating method, a roll coating method, a screen printing method, an applicator method, or the like, in a desired thickness of, e.g., 2 to 25 μm. In addition, as a light source used for the exposure (irradiation), a low-pressure mercury lamp, a high-pressure mercury lamp, an extra high-pressure mercury lamp, a metal halide lamp, an argon gas laser, or the like may be used. X-ray, electronic ray, or the like may also be used, if desired. The photosensitive resin composition of the present invention is capable of forming a cured film that is excellent in terms of the heat resistance, transparency, dielectric constant, solvent resistance, acid resistance, and alkali resistance. Therefore, the cured film of the present invention thus formed has excellent light transmittance devoid of surface roughness when it is subjected to heat treatment or is immersed in, or comes into contact with a solvent, an acid, a base, or the like. Thus, the cured film can be effectively used as a planarization film for a thin-film transistor (TFT) substrate of a liquid crystal display or an organic EL display; a partition of an organic EL display; an interlayer dielectric of a semiconductor device; a core or cladding material of an optical waveguide, or the like. Further, the present invention provides an electronic part that comprises the cured film as a protective film.

### MODE FOR THE INVENTION

Hereinafter, the present invention will be described in more detail with reference to the following examples. However, these examples are provided to illustrate the present invention, and the scope of the present invention is not limited thereto only. In the following preparation examples, the weight average molecular weight is determined by gel permeation chromatography (GPC, eluent: tetrahydrofuran) referenced to a polystyrene standard.

### EXAMPLE

### Preparation Example 1: Preparation of a Siloxane Copolymer (A)

A reactor equipped with a reflux condenser was charged with 40% by weight of phenyltrimethoxysilane, 15% by weight of methyltrimethoxysilane, 20% by weight of tetraethoxysilane, and 20% by weight of distilled water and 5% by weight of propylene glycol monomethyl ether acetate (PGMEA) as a solvent, followed by refluxing and vigorously stirring the mixture for 7 hours in the presence of 0.1% by weight of an oxalic acid catalyst. Then, the mixture was cooled and diluted with PGMEA such that the solids content was 40%. As a result, a siloxane copolymer (A) having a weight average molecular weight of 5,000 to 10,000 Da was prepared.

### Preparation Example 2: Preparation of an Acrylic Copolymer (B-1)

A flask equipped with a cooling tube and a stirrer was charged with 200% by weight of PGMEA as a solvent, and the temperature of the solvent was raised to 70° C. while the solvent was slowly stirred. Next, added thereto were 20% by weight of styrene, 32% by weight of methacrylate, 15% by weight of glycidyl methacrylate, 19% by weight of methacrylic acid, and 14% by weight of methyl acrylate, followed by dropwise adding of 3% by weight of 2,2′-azobis(2,4-dimethylvaleronitrile) as a radical polymerization initiator over 5 hours to carry out a polymerization reaction. Next, the resultant was diluted with PGMEA such that the solids content was 32% by weight. As a result, an acrylic copolymer (B-1) having a weight average molecular weight of 9,500 Da was prepared.

### Preparation Example 3: Preparation of an Acrylic Copolymer (B-1)

An acrylic copolymer (B-2) having a solids content of 32% by weight and a weight average molecular weight of 11,500 Da was prepared in the same manner as in Preparation Example 2, except that 20% by weight of styrene, 30% by weight of methacrylate, 15% by weight of glycidyl methacrylate, 21% by weight of methacrylic acid, and 14% by weight of methyl acrylate were employed.

### Preparation Example 4: Preparation of an Epoxy Compound (D)

A three-necked flask was equipped with a cooling tube and placed on a stirrer equipped with a thermostat. The flask was charged with 100 parts by weight of a monomer composed of 100% by mole of glycidyl methacrylate, 10 parts by weight of 2,2′-azobis(2-methylbutyronitrile), and 100 parts by weight of PGMEA, followed by charging nitrogen thereto. Thereafter, the temperature of the solution was raised to 80° C. while the solution was slowly stirred, and the temperature was maintained for 5 hours. Next, the resultant was diluted with PGMEA such that the solids content was 20% by weight. As a result, an epoxy compound (D) having a weight average molecular weight of 3,000 to 6,000 Da was prepared.

### EXAMPLES AND COMPARATIVE EXAMPLES: PREPARATION OF POSITIVE-TYPE PHOTOSENSITIVE RESIN COMPOSITIONS

The photosensitive resin compositions of the following Examples and Comparative Examples were each prepared using the compounds prepared in the above Preparation Examples.

The components used in the following Examples and Comparative Examples are as follows.

TABLE 1

| | | | | Solids content | |
|---|---|---|---|---|---|
| Component | | | | (% by weight) | Manufacturer |
| Siloxane copolymer (A) | | | Preparation Example 1 | 40 | — |
| Acrylic | | B-1 | Preparation Example 2 | 32 | — |
| copolymer (B) | | B-2 | Preparation Example 3 | 32 | — |
| Photoactive | c-1 | C-1 | Polymer PAC (MCAD1040) | 100 | Shinryo Corp. |
| compound | | | CAS No. 142443-61-6 | | |
| (C) | | C-2 | Polymer PAC (D4 PAC) | 100 | Shinryo Corp. |
| | | | CAS No. 181229-58-3 | | |
| | c-2 | C-3 | monomer PAC (THA-523) | 100 | Miwon |
| | | C-4 | monomer PAC (TPA-523) | 100 | Miwon |

| Epoxy compound (D) | | Preparation Example 4 | 20 | — |
|---|---|---|---|---|
| Surfactant (E) | | Silicone-based leveling | 100 | Dow Corning |
| | | surfactant, FZ-2122 | | Toray |
| Solvent (G) | G-1 | Propylene glycol monomethyl | — | Chemtronics |
| | | ether acetate (PGMEA) | | |
| | G-2 | Dipropylene glycol dimethyl | — | Chemtronics |
| | | ether | | |
| | G-3 | Methyl 3-methoxypropionate | — | Hannong |

### Example 1

24.15% by weight and 33.64% by weight (57.79% by weight in total) of the acrylic copolymers (B-1) and (B-2) prepared in Preparation Examples 2 and 3 were mixed. In such event, the contents of the acrylic copolymers (B-1) and (B-2) were based on the total weight of the photosensitive resin composition (on the basis of the solids content excluding the solvent).

Next, 44.78 parts by weight of the siloxane copolymer (A) prepared in Preparation Example 1, 4.48 parts by weight of the epoxy compound (D) prepared in Preparation Example 4, 3.5 parts by weight of a polymer photoactive compound (C-1), 11.91 parts by weight of TPA-523 (C-3) and 7.94 parts by weight of THA-523 (C-4) as a monomer photoactive compound (C-2), and 0.42 part by weight of FZ-2122 as a surfactant (E), based on 100 parts by weight of the total weight of the acrylic copolymer (B) (i.e., the sum of (B-1) and (B-2)), were homogeneously mixed. The mixture was dissolved in a mixed solvent of PGMEA, DPGDME, and MMP (PGMEA:DPGDME:MMP=82:10:8) for 3 hours such that the solids content of the mixture was 19% by weight. The resultant was stirred for 2 hours and filtered through a membrane filter having a pore size of 0.2 μm to obtain a photosensitive resin composition solution having a solids content of 22% by weight.

### Examples 2 to 6 and Comparative Example 1

Photosensitive resin composition solutions were each prepared in the same manner as in Example 1, except that the kinds and/or the contents of the respective components were changed as shown in Table 2 below.

TABLE 2

| | Siloxane | Acrylic | | Photoactive compound (C) | | | | Epoxy | |
|---|---|---|---|---|---|---|---|---|---|
| | copolymer | copolymer (B) | | c-1 | | c-2 | | compound | Surfactant |
| | (A) | B-1 | B-2 | C-1 | C-2 | C-3 | C-4 | (D) | (E) |
| Ex. 1 | 44.78 | 41.79 | 58.21 | 3.50 | 0.00 | 11.91 | 7.94 | 4.48 | 0.42 |
| Ex. 2 | 44.78 | 41.79 | 58.21 | 5.84 | 0.00 | 10.51 | 7.01 | 4.48 | 0.42 |
| Ex. 3 | 44.78 | 42.79 | 58.22 | 8.18 | 0.00 | 9.11 | 6.07 | 4.48 | 0.42 |
| Ex. 4 | 44.78 | 43.79 | 58.23 | 11.68 | 0.00 | 6.94 | 4.68 | 4.48 | 0.42 |
| Ex. 5 | 44.78 | 44.79 | 58.24 | 0.00 | 5.84 | 10.51 | 7.01 | 4.48 | 0.42 |
| Ex. 6 | 44.78 | 45.79 | 58.25 | 0.00 | 8.18 | 9.11 | 6.07 | 4.48 | 0.42 |
| C. Ex. 1 | 44.78 | 46.79 | 58.26 | 0.00 | 0.00 | 14.02 | 9.34 | 4.48 | 0.42 |

### Evaluation Example

### Evaluation Example 1: Rate of Loss Upon Development

The compositions prepared in the Examples and the Comparative Examples were each coated onto a glass substrate by spin coating. The coated substrate was then pre-baked on a hot plate kept at 105° C. for 105 seconds to form a dry film. The thickness (T1) of the dried film upon the pre-bake was measured using a non-contact-type thickness measurement equipment (SNU Precision).

A mask having a pattern of square holes in a size ranging from 1 μm to 30 μm was placed on the dried film. The film was then exposed to light at an exposure rate of 0 to 200 mJ/cm² based on a wavelength of 365 nm with a gap between the mask and the substrate of 25 μm based on the light exposure for a certain time period using an aligner (model name: MA6) that emits light having a wavelength of 200 nm to 450 nm (i.e., bleaching step). The exposed film was developed with an aqueous developer of 2.38% by weight of tetramethylammonium hydroxide through puddle nozzles at 23° C. for 80 seconds. The thickness (T2) of the film upon the development was measured.

The rate of loss in thickness of the cured film upon the development step was calculated from the measured values by the following Equation 1.

Rate of loss upon development=thickness (T2) upon development−initial thickness (T1) [Equation 1]

As the rate of loss upon development is smaller than 10,000 Å, it is evaluated that a more stable cured film is formed as the film retention rate is excellent.

### Evaluation Example 2: Evaluation of Resolution and Sensitivity

A development step was carried out in the same manner as in Evaluation Example 1. The developed film was then exposed to light at an exposure rate of 40 mJ/cm² and 80 mJ/cm² based on a wavelength of 365 nm for a certain time period using an aligner (model name: MA6) that emits light having a wavelength of 200 nm to 450 nm (i.e., bleaching step). The exposed film was heated in a convection oven at 230° C. for 30 minutes to prepare a cured film having a thickness of 3.5 μm. For the hole pattern formed per a size of the mask of 11 μm in the above procedure, the amount of exposure energy for attaining a critical dimension (CD, unit: μm) of 11 μm was measured. The lower the value (mJ/cm²), the better the sensitivity.

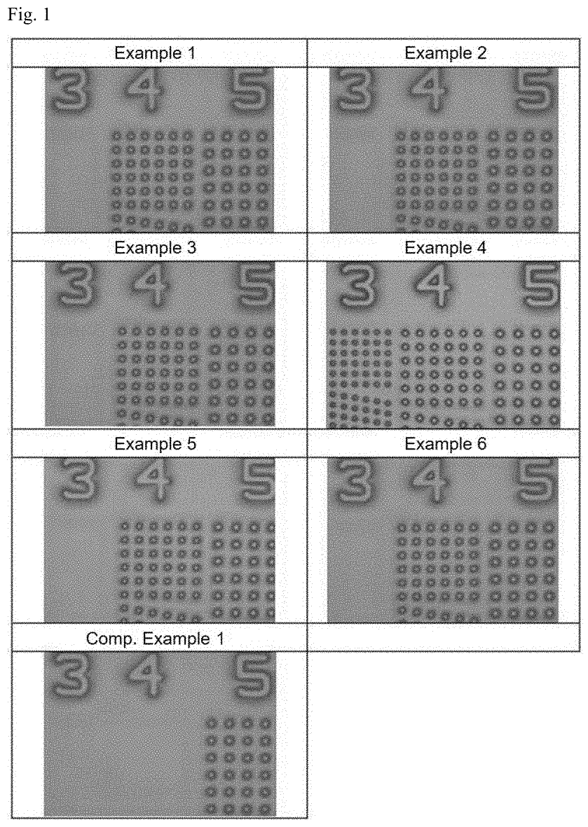

In addition, the hole pattern of the cured film was photographed using a micro-optical microscope (STM6-LM, manufacturer: OLYMPUS) and is shown in FIG. 1.

The lower the size of the hole pattern and the smaller the value of sensitivity, the more excellent the resolution.

### Evaluation Example 3: Evaluation of Film Retention Rate

The compositions prepared in the Examples and the Comparative Examples were each subjected to pre-bake, exposure to light through a mask, development, and thermal curing in the same manner as in Evaluation Example 2, thereby obtaining a cured film. In such event, the film retention rate (%) was obtained by calculating the ratio in a percent of the thickness of the final film upon the post-bake to the thickness of the film upon the pre-bake using a non-contact-type thickness measurement equipment (SNU Precision).

Evaluation Example 4: Evaluation of Appearance of a Cured Film—Evaluation of Surface Characteristics

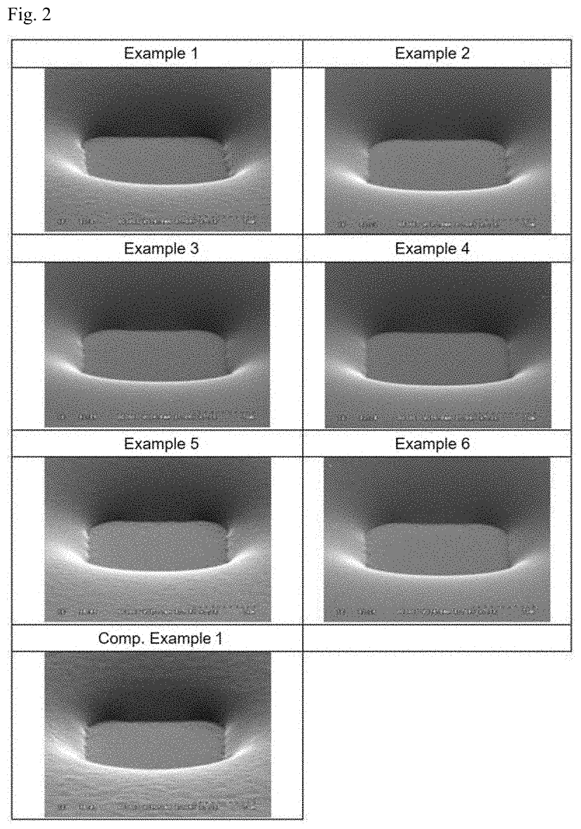

The surface of the cured film obtained in Evaluation Example 2 was photographed using a scanning electron microscope (SEM) to check the degree of roughness. The results are shown in Table 3 below and FIG. 2.

The degree of roughness was graded as ∘, Δ, x, and the surface roughness characteristics were evaluated to be excellent when the surface roughness was ∘ or Δ.

(If the surface was smooth and clean without irregularities when observed by the naked eyes, it is close to ∘; if the surface is rough with irregularities, it is close to x.)

TABLE 3

| | Rate of | | | | |
|---|---|---|---|---|---|
| | loss upon | Reso- | Film | Surface | Sensi- |
| | development | lution | retention | charac- | tivity |
| | (Å) | (μm) | rate (%) | teristics | (mJ/cm²) |
| Ex. 1 | 9,728 | 4 | 71.26 | Δ | 60 |
| Ex. 2 | 8,837 | 4 | 72.78 | ∘ | 55 |
| Ex. 3 | 8,281 | 4 | 73.45 | ∘ | 55 |
| Ex. 4 | 7,639 | 3 | 74.55 | ∘ | 50 |
| Ex. 5 | 8,647 | 4 | 72.92 | ∘ | 55 |
| Ex. 6 | 8,095 | 4 | 73.65 | ∘ | 55 |
| C. Ex. 1 | 12,642 | 5 | 67.22 | x | 65 |

As shown in Table 3 and FIGS. 1 and 2, all of the cured films prepared from the compositions of Examples, falling within the scope of the present invention, had rates of loss in thickness upon development of 10,000 Å or less and were excellent in such properties as resolution, sensitivity, and film retention rate, as well as excellent in surface characteristics. In contrast, the cured film prepared from the composition of Comparative Example 1 had a large rate of loss upon development, which indicates that the loss in thickness during the development step was significant, and was poor in resolution and sensitivity, as well as surface characteristics, as compared with the cured films of the Examples.

1. A positive-type photosensitive resin composition, which comprises:
(A) a siloxane copolymer;
(B) an acrylic copolymer; and
(C) a photoactive compound comprising a compound containing a repeat unit represented by the following Formula 1: 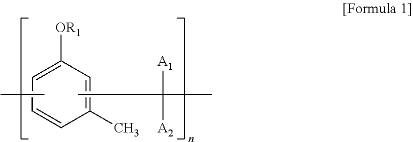
in the above Formula 1,
A₁ and A₂ are each independently hydrogen, a hydroxyl group, a phenol group, a C₁₋₄ alkyl group, a C₆₋₁₅ aryl group, or a C₁₋₄ alkoxy group,
R₁ is hydrogen or 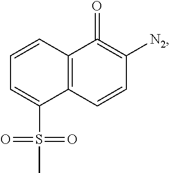
and
n is an integer of 3 to 15.

2. The positive-type photosensitive resin composition of claim 1, wherein the siloxane polymer (A) comprises a structural unit derived from a silane compound represented by the following Formula 2:
(R₂)ₘSi(OR₃)₄₋ₘ [Formula 2]
in the above Formula 2,
m is an integer of 0 to 3,
R₂ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl, and
R₃ is each independently hydrogen, C₁₋₆ alkyl, C₂₋₆ acyl, or C₆₋₁₅ aryl,
wherein the heteroalkyl, the heteroalkenyl, and the heteroaryl groups each independently have at least one heteroatom selected from the group consisting of O, N, and S.

3. The positive-type photosensitive resin composition of claim 2, wherein the siloxane polymer (A) comprises a structural unit derived from a silane compound represented by the above Formula 2 where m is 0.

4. The positive-type photosensitive resin composition of claim 1, wherein the acrylic copolymer (B) comprises (b-1) a structural unit derived from an ethylenically unsaturated carboxylic acid, an ethylenically unsaturated carboxylic anhydride, or a combination thereof; (b-2) a structural unit derived from an unsaturated compound containing an epoxy group; and (b-3) a structural unit derived from an ethylenically unsaturated compound different from the structural units (b-1) and (b-2).

5. The positive-type photosensitive resin composition of claim 1, which comprises the acrylic copolymer (B) in an amount of 10 to 90% by weight based on the total weight of the photosensitive resin composition (on the basis of the solids content).

6. The positive-type photosensitive resin composition of claim 1, wherein the photoactive compound (C) further comprises a quinonediazide-based compound.

7. The positive-type photosensitive resin composition of claim 1, which further comprises an epoxy compound (D).

8. The positive-type photosensitive resin composition of claim 1, which further comprises (E) a surfactant, (F) an adhesion supplement, or a combination thereof.

9. A cured film prepared from the positive-type photosensitive resin composition of claim 1.
